(19) United States
(12) Patent Application Publication
(10) Pub. No.: US 2024/0006462 A1
(43) Pub. Date: Jan. 4, 2024

(54) LIGHT-EMITTING APPARATUS AND METHOD FOR PRODUCING LIGHT-EMITTING APPARATUS

(71) Applicant: SONY GROUP CORPORATION, Tokyo (JP)

(72) Inventors: Yasunobu IWAKOSHI, Tokyo (JP); Jun SUZUKI, Tokyo (JP)

(73) Assignee: SONY GROUP CORPORATION, Tokyo (JP)

(21) Appl. No.: 18/255,541

(22) PCT Filed: Dec. 2, 2021
(86) PCT No.: PCT/JP2021/044202

§ 371 Date: Jun. 1, 2023

(30) Foreign Application Priority Data
Dec. 11, 2020 (JP) 2020-205594

(51) Int. Cl. H01L 27/15; H01L 33/00; H01L 33/58

(52) U.S. Cl. CPC H01L 27/156; H01L 33/0095; H01L 33/58

(57) ABSTRACT

A light-emitting apparatus that has a structure that is highly productive and suitable for arranging light-emitting elements at a high density, and a method for producing the light-emitting apparatus, are provided. The light-emitting apparatus includes a substrate, a drive element, a light-emitting element, and an interlayer insulation layer. The substrate includes a front surface and a back surface. The drive element is mounted on a first mounting surface on a side of the front surface of the substrate. The light-emitting element is mounted on a second mounting surface on the side of the front surface of the substrate, the second mounting surface being situated at a distance from the substrate front surface; that is different from a distance of the first mounting surface from the substrate front surface. The interlayer insulation layer is made of an insulating material and formed between the drive element and the light-emitting element.

### TECHNICAL FIELD

The present technology relates to a light-emitting apparatus that can be used for, for example, a display, and a method for producing the light-emitting apparatus.

### BACKGROUND ART

In general, light-emitting apparatuses used in, for example, a display have a structure in which a light-emitting element and a drive element that drives the light-emitting element are mounted on a substrate. For example, as an example of a structure in which a light-emitting element and a drive element are mounted on a surface of a substrate, Patent Literature 1 discloses a mounting substrate in which a light-emitting element and a drive IC are mounted on a surface of the mounting substrate.

Further, as an example of a structure in which a light-emitting element and a drive element are respectively mounted on one of front and back surfaces of a substrate, and on another of the front and back surfaces of the substrate, Patent Literature 2 discloses a display apparatus that includes a printed circuit board, a light-emitting element mounted on one of front and back surfaces of the printed circuit board, and a control component mounted on another of the front and back surfaces of the printed circuit board. Furthermore, Patent Literature 3 discloses a light-emitting apparatus that includes a substrate, a light-emitting element mounted on one of front and back surfaces of the substrate, and a driver IC mounted on another of the front and back surfaces of the substrate.

### CITATION LIST

### Patent Literature

Patent Literature 1: Japanese Patent Application Laid-open No. 2015-197544

Patent Literature 2: Japanese Patent Application Laid-open No. 9-223820

Patent Literature 3: Japanese Patent Application Laid-open No. 2014-149489

### DISCLOSURE OF INVENTION

### Technical Problem

However, there is a need to arrange a drive element between light-emitting elements in a configuration in which the light-emitting element and the drive element are mounted on a surface of a substrate, as disclosed in Patent Literature 1. This results in difficulty in mounting the light-emitting elements at a high density. Further, a configuration in which a light-emitting element and a drive element are respectively mounted on one of front and back surfaces of a substrate and on another of the front and back surfaces of the substrate, as disclosed in Patent Literatures 2 and 3, results in a complicated mounting process.

In view of the circumstances described above, it is an object of the present technology to provide a light-emitting apparatus that has a structure that is highly productive and suitable to arrange light-emitting elements at a high density, and a method for producing the light-emitting apparatus.

### Solution to Problem

In order to achieve the object described above, a light-emitting apparatus according to an embodiment of the present technology includes a substrate, a drive element, a light-emitting element, and an interlayer insulation layer.

The substrate includes a substrate front surface and a substrate back surface that is situated opposite to the substrate front surface.

The drive element is mounted on a first mounting surface on a side of the substrate front surface of the substrate.

The light-emitting element is mounted on a second mounting surface on the side of the substrate front surface of the substrate, the second mounting surface being situated at a distance, from the substrate front surface, that is different from a distance of the first mounting surface from the substrate front surface.

The interlayer insulation layer is made of an insulating material and formed between the drive element and the light-emitting element.

When a direction in which light emitted by the light-emitting element is emitted is a light-emitting direction, the first mounting surface may be situated opposite to an orientation of the light-emitting direction with respect to the second mounting surface.

The light-emitting apparatus may further include a black matrix that is arranged on the side of the substrate front surface of the substrate and absorbs incident light, the black matrix including an opening that faces the light-emitting element.

The light-emitting apparatus may further include a protection layer that covers the light-emitting element, and the black matrix may be arranged on the protection layer.

The black matrix may be arranged on the second mounting surface.

The second mounting surface may be situated farther away from the substrate front surface than the first mounting surface.

The interlayer insulation layer may be stacked on the substrate front surface and may include a first layer surface and a second layer surface, the first layer surface being situated on the side of the substrate front surface, the second layer surface being situated opposite to the first layer surface, the first mounting surface may be the substrate front surface, and the second mounting surface may be the second layer surface.

The first mounting surface may be situated farther away from the substrate front surface than the second mounting surface.

The light-emitting apparatus may further include a protection layer that is stacked on the substrate front surface, the interlayer insulation layer may be stacked on the protection layer and may include a first layer surface and a second layer surface, the first layer surface being situated on the side of the substrate front surface, the second layer surface being situated opposite to the first layer surface, the protection layer may include a third layer surface and a fourth layer surface, the third layer surface being situated on the side of the substrate front surface, the fourth layer surface being situated opposite to the third layer surface, the first mounting surface may be the second layer surface, and the second mounting surface may be the fourth layer surface.

The light-emitting apparatus may further include first wiring that is provided on the first mounting surface and connected to the drive element, and second wiring that connects the drive element and the light-emitting element.

The second wiring may be provided on the first mounting surface, on the second mounting surface, and in the interlayer insulation layer.

The second wiring may be provided in the interlayer insulation layer and does not have to be provided on the second mounting surface.

A black matrix that absorbs incident light and includes an opening that faces the light-emitting element, may be arranged on the second mounting surface.

A sealing body that seals the light-emitting element may be provided on the second mounting surface.

The second wiring may be provided in the interlayer insulation layer and does not have to be provided on the first mounting surface.

The interlayer insulation layer may shield the drive element from light emitted by the light-emitting element.

The drive element may be a thin film transistor.

The drive element may be an integrated circuit.

In order to achieve the object described above, a method for producing a light-emitting apparatus according to an embodiment of the present technology includes mounting a drive element on a first mounting surface on a side of a substrate front surface of a substrate, the substrate including the substrate front surface and a substrate back surface that is situated opposite to the substrate front surface; connecting the drive element and first wiring on the side of the substrate front surface of the substrate; testing the drive element; when an error has occurred in the drive element, repairing the drive element in which the error has occurred; mounting a light-emitting element on a second mounting surface on the side of the substrate front surface of the substrate, the second mounting surface being situated at a distance, from the substrate front surface, that is different from a distance of the first mounting surface from the substrate front surface; connecting the light-emitting element and second wiring on the side of the substrate front surface of the substrate; testing the light-emitting element; and when an error has occurred in the light-emitting element, repairing the light-emitting element in which the error has occurred.

In order to achieve the object described above, a method for producing a light-emitting apparatus according to an embodiment of the present technology includes mounting a light-emitting element on a second mounting surface on a side of a substrate front surface of a substrate, the substrate including the substrate front surface and a substrate back surface that is situated opposite to the substrate front surface; connecting the light-emitting element and second wiring on the side of the substrate front surface of the substrate; testing the light-emitting element; when an error has occurred in the light-emitting element, repairing the light-emitting element in which the error has occurred; mounting a drive element on a first mounting surface on the side of the substrate front surface of the substrate, the first mounting surface being situated at a distance, from the substrate front surface, that is different from a distance of the second mounting surface from the substrate front surface; connecting the drive element and first wiring on the side of the substrate front surface of the substrate; testing the drive element; and when an error has occurred in the drive element, repairing the drive element in which the error has occurred.

### BRIEF DESCRIPTION OF DRAWINGS

FIG. 1 is a cross-sectional view of a light-emitting apparatus according to a first embodiment of the present technology.

FIG. 2 is an exploded cross-sectional view of the light-emitting apparatus.

FIG. 3 is a plan view of the light-emitting apparatus.

FIG. 4 is a plan view illustrating a configuration of a portion of the light-emitting apparatus.

FIG. 5 schematically illustrates second wiring that is included in the light-emitting apparatus.

FIG. 6 schematically illustrates a distance between a first mounting surface and a substrate front surface and a distance between a second mounting surface and the substrate front surface.

FIG. 7 schematically illustrates an operation of the light-emitting apparatus.

FIG. 8 schematically illustrates a method for producing the light-emitting apparatus.

FIG. 9 schematically illustrates the method for producing the light-emitting apparatus.

FIG. 10 schematically illustrates the method for producing the light-emitting apparatus.

FIG. 11 is a cross-sectional view of a light-emitting apparatus according to a comparative example of the present technology.

FIG. 12 is a plan view of the light-emitting apparatus.

FIG. 13 schematically illustrates a relationship between a thickness of a protection layer and a size of an opening of a black matrix in the light-emitting apparatus according to the first embodiment of the present technology.

FIG. 14 is a cross-sectional view of the light-emitting apparatus according to a modification of the first embodiment of the present technology.

FIG. 15 is a cross-sectional view of the light-emitting apparatus according to a modification of the first embodiment of the present technology.

FIG. 16 is a cross-sectional view of the light-emitting apparatus according to a modification of the first embodiment of the present technology.

FIG. 17 is a cross-sectional view of the light-emitting apparatus according to a modification of the first embodiment of the present technology.

FIG. 18 is a cross-sectional view of the light-emitting apparatus according to a modification of the first embodiment of the present technology.

FIG. 19 is a cross-sectional view of the light-emitting apparatus according to a modification of the first embodiment of the present technology.

FIG. 20 is a cross-sectional view of a light-emitting apparatus according to a second embodiment of the present technology.

FIG. 21 is an exploded cross-sectional view of the light-emitting apparatus.

FIG. 22 schematically illustrates a distance between the first mounting surface and a substrate front surface and a distance between the second mounting surface and the substrate front surface.

FIG. 23 schematically illustrates an operation of the light-emitting apparatus.

### MODE(S) FOR CARRYING OUT THE INVENTION

A light-emitting apparatus according to each embodiment of the present technology is described. The light-emitting apparatus according to each embodiment of the present technology is a light-emitting apparatus that can be used for, for example, a backlight of a display panel or a display.

### First Embodiment

A light-emitting apparatus according to a first embodiment of the present technology is described.

### [Structure of Light-Emitting Apparatus]

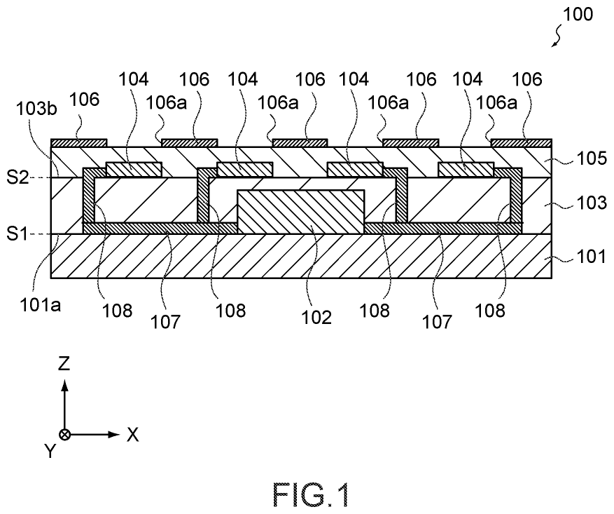

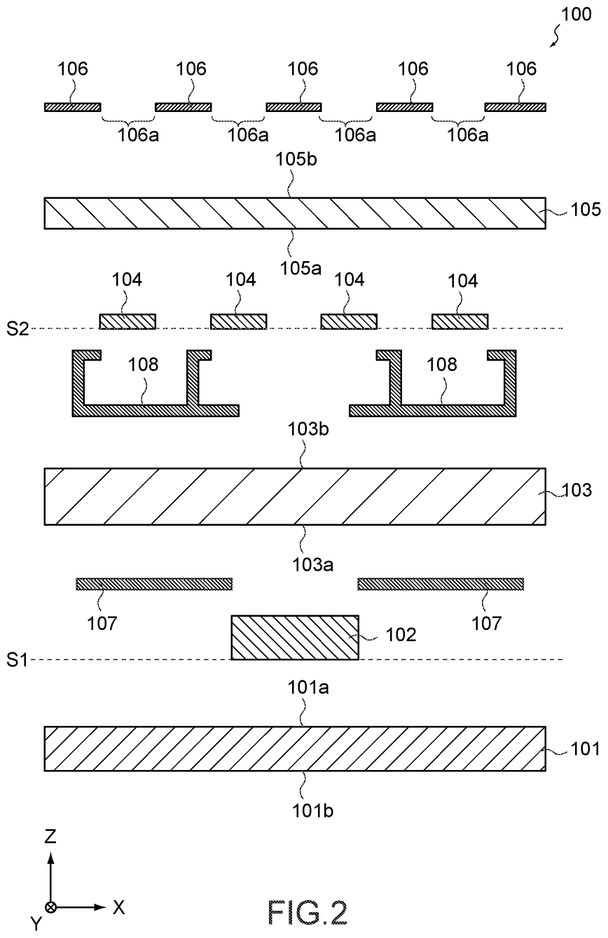

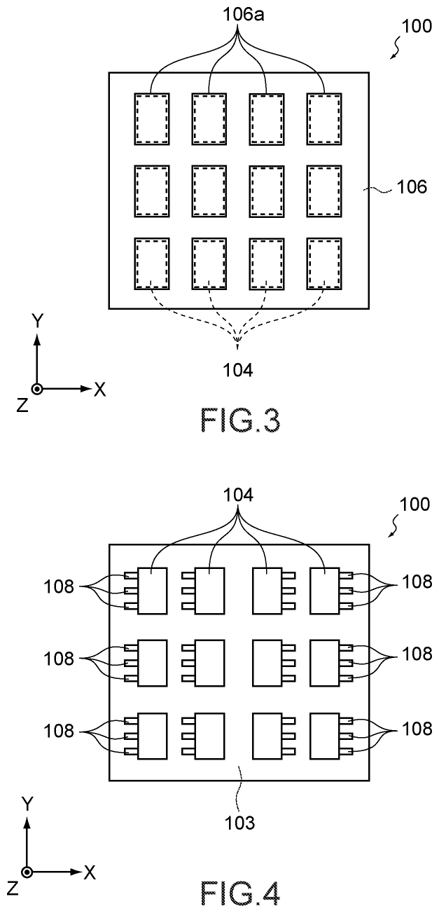

A structure of the light-emitting apparatus according to the present embodiment is described. FIG. 1 is a cross-sectional view of a light-emitting apparatus 100 according to the present embodiment, and FIG. 2 is an exploded cross-sectional view of the light-emitting apparatus 100. FIG. 3 is a plan view of the light-emitting apparatus 100, and FIG. 4 is a plan view illustrating a configuration of a portion of the light-emitting apparatus 100. Note that, in each figure of the present disclosure, a direction of light emission performed by the light-emitting apparatus 100 is referred to as a Z direction, a direction that is orthogonal to the Z direction is referred to as an X direction, and a direction that is orthogonal to the X direction and the Z direction is referred to as a Y direction. The X direction and the Y direction are directions that extend in parallel with a direction of a layer plane of each layer of the light-emitting apparatus 100, and the Z direction is a direction that extend in parallel with a direction in which the respective layers of the light-emitting apparatus 100 are stacked.

As illustrated in FIGS. 1 and 2, the light-emitting apparatus 100 includes a substrate 101, a drive element 102, an interlayer insulation layer 103, a light-emitting element 104, a protection layer 105, a black matrix 106, first wiring 107, and second wiring 108.

The substrate 101 supports each layer of the light-emitting apparatus 100. As illustrated in FIG. 2, the substrate 101 includes a substrate front surface 101a and a substrate back surface 101b that is a surface situated opposite to the substrate front surface 101a. A material of the substrate 101 is not particularly limited, and may be, for example, glass or an organic material.

The drive element 102 drives the light-emitting element 104. The drive element 102 may be a thin film transistor (TFT) or an integrated circuit. As illustrated in FIG. 2, the drive element 102 is mounted on the first mounting surface S1. As illustrated in FIG. 1, the first mounting surface S1 may be the substrate front surface 101a. FIG. 1 illustrates a single drive element 102, but the light-emitting apparatus 100 may include a plurality of drive elements 102 arranged in a matrix. Further, the light-emitting apparatus 100 may include a single drive element 102.

The interlayer insulation layer 103 is formed between the drive element 102 and the light-emitting element 104, and insulates the drive element 102 from the light-emitting element 104. The interlayer insulation layer 103 may be stacked on the substrate front surface 101a of the substrate 101 and on the drive element 102. As illustrated in FIG. 2, from among layer surfaces of the interlayer insulation layer 103, a surface situated on a side of the substrate front surface 101a is referred to as a first layer surface 103a, and a surface situated opposite to the first layer surface 103a is referred to as a second layer surface 103b. A material of the interlayer insulation layer 103 may be any insulating material, and is favorably a material exhibiting excellent light-blocking properties. The interlayer insulation layer 103 favorably exhibits a light transmittance less than or equal to 1% at a wavelength of light emitted by the light-emitting element 104.

The light-emitting element 104 emits light. The light-emitting element 104 may be a semiconductor light-emitting element such as a light-emitting diode (LED) or a laser diode (LD), and may operate as, for example, a pixel (pixels of R, G, and B) of a display, or a light source of a backlight. The wavelength of light emitted by the light-emitting element 104 is not limited to wavelengths of, for example, visible light, ultraviolet light, and infrared light. The respective light-emitting elements 104 may emit light at different wavelengths. As illustrated in FIG. 2, the light-emitting element 104 is mounted on the second mounting surface S2. As illustrated in FIG. 1, the second mounting surface S2 may be the second layer surface 103b of the interlayer insulation layer 103. The light-emitting apparatus 100 may include a plurality of light-emitting elements 104 arranged in a matrix, or a single light-emitting element 104.

The protection layer 105 covers the light-emitting element 104 and protects the light-emitting element 104. The protection layer 105 may be stacked on the interlayer insulation layer 103 and on the light-emitting element 104. As illustrated in FIG. 2, from among layer surfaces of the protection layer 105, a surface situated on the side of the substrate front surface 101a is referred to as a third layer surface 105a, and a surface situated opposite to the first layer surface 105a is referred to as a fourth layer surface 105b. A material of the protection layer 105 may be any insulating material, and is favorably a material exhibiting a high degree of light transmittance at a wavelength of light emitted by the light-emitting element 104.

The black matrix 106 absorbs incident light. The black matrix 106 may be formed on the protection layer 105. As illustrated in FIG. 3, the black matrix 106 includes an opening 106a. The opening 106a faces the light-emitting element 104, and is formed such that the black matrix 106 does not block light emitted by the light-emitting element 104.

The first wiring 107 is wiring that is connected to the drive element 102. As illustrated in FIG. 1, the first wiring 107 is provided on the substrate front surface 101a, that is, on the first mounting surface S1. The first wiring 107 is made of any conductive material.

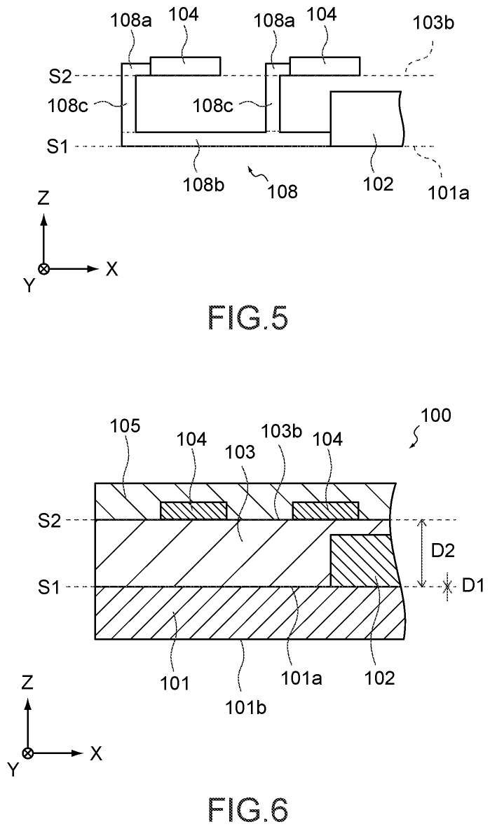

The second wiring 108 is wiring that connects the drive element 102 and the light-emitting element 104. FIG. 5 schematically illustrates the second wiring 108. As illustrated in the figure, the second wiring 108 includes a first portion 108a, a second portion 108b, and a third portion 108c. The first portion 108a is connected to the light-emitting element 104 and provided on the second layer surface 103b of the interlayer insulation layer 103, that is, on the second mounting surface S2. The second portion 108b is connected to the drive element 102 and provided on the substrate front surface 101a, that is, on the first mounting surface S1. The third portion 108c connects the first portion 108a and the second portion 108b and provided in the interlayer insulation layer 103. Note that the second portion 108b is provided on the substrate front surface 101a to be spaced from the first wiring 107. The second wiring 108 is made of any conductive material.

### [Regarding First Mounting Surface and Second Mounting Surface]

As described above, the drive element 102 is arranged on the first mounting surface S1, and the light-emitting element 104 is arranged on the second mounting surface S2. Both the first mounting surface S1 and the second mounting surface S2 are surfaces that are situated on the side of the substrate front surface 101a of the substrate 101 and parallel to the layer plane (an X-Y plane) of each layer. Here, the second mounting surface S2 may be situated farther away from the substrate front surface 101a than the first mounting surface S1. FIG. 6 schematically illustrates a distance between the first mounting surface S1 and the substrate front surface 101a and a distance between the second mounting surface S2 and the substrate front surface 101a.

When the distance between the first mounting surface S1 and the substrate front surface 101a is referred to as a distance D1 and the distance between the second mounting surface S2 and the substrate front surface 101a is referred to as a distance D2, the distance D2 may be larger than the distance D1, as illustrated in the figure. In the configuration described above, the distance D1 is zero since the first mounting surface S1 is in plane with the substrate front surface 101a. However, the first mounting surface S1 may be spaced from the substrate front surface 101a. In this case, the distance D1 is a distance larger than zero and smaller than the distance D2.

The light-emitting apparatus 100 has the configuration above. The light-emitting apparatus 100 may have a configuration in which twelve light-emitting elements 104 are connected to a single drive element 102, as illustrated in FIGS. 1 and 4. The number of light-emitting elements 104 connected to a single drive element 102 is not particularly limited, and may be any number that is at least one.

### [Operation of Light-Emitting Apparatus]

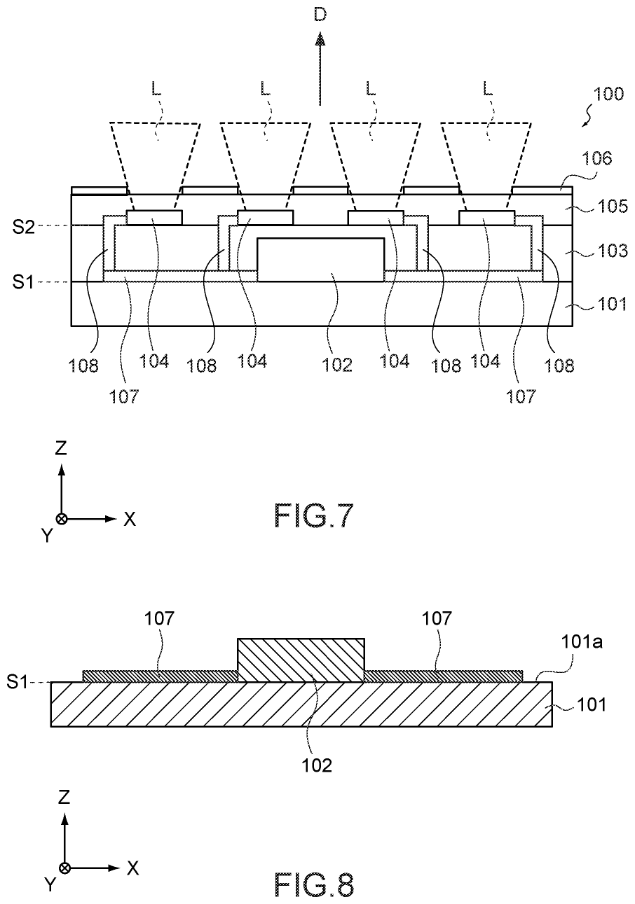

An operation of the light-emitting apparatus 100 is described. FIG. 7 schematically illustrates the operation of the light-emitting apparatus 100. When a drive signal is supplied to the drive element 102 from the outside through the first wiring 107, the drive element 102 generates a drive signal for each light-emitting element 104, and supplies the generated drive signal to the light-emitting element 104 through the second wiring 108. When the drive signal is supplied to each light-emitting element 104 by the drive element 102, the light-emitting element 104 emits light L, as illustrated in FIG. 7. The light L coming from the light-emitting element 104 is transmitted through the protection layer 105, and passes through the opening 106a (refer to FIG. 2) of the black matrix 106 to be emitted.

A direction in which the light L is emitted by the light-emitting apparatus 100 is referred to as a light-emission direction D, as indicated by an arrow in FIG. 7. As described above, the light-emitting apparatus 100 may have a top-emitting structure in which the light L is emitted in a direction opposite to the substrate 101.

With respect to a relationship between the light-emitting direction D, the first mounting surface S1, and the second mounting surface S2, the first mounting surface S1 is situated opposite to the orientation of the light-emitting direction D with respect to the second mounting surface S2. This results in the drive element 102 not blocking the light L emitted by the light-emitting element 104, and thus in being able to increase a degree of freedom in the size and arrangement of the drive element 102.

### [Method for Producing Light-Emitting Apparatus]

A method for producing the light-emitting apparatus 100 is described. FIGS. 8 to 10 schematically illustrate the method for producing the light-emitting apparatus 100. First, the drive element 102 is mounted on the substrate front surface 101a (the first mounting surface S1) on which the first wiring 107 is formed, and the drive element 102 and the first wiring 107 are connected to each other, as illustrated in FIG. 8.

After the drive element 102 is mounted, the drive element 102 is tested, and an error in the drive element 102 is detected. Examples of the error include a malfunction in the drive element 102 itself and a failure in connection between the drive element 102 and the first wiring 107. When an error has occurred in the drive element 102, the drive element 102 is repaired. In the case of repairing the drive element 102, the drive element 102 may be connected to the first wiring 107 again, or the drive element 102 may be replaced with another drive element 102.

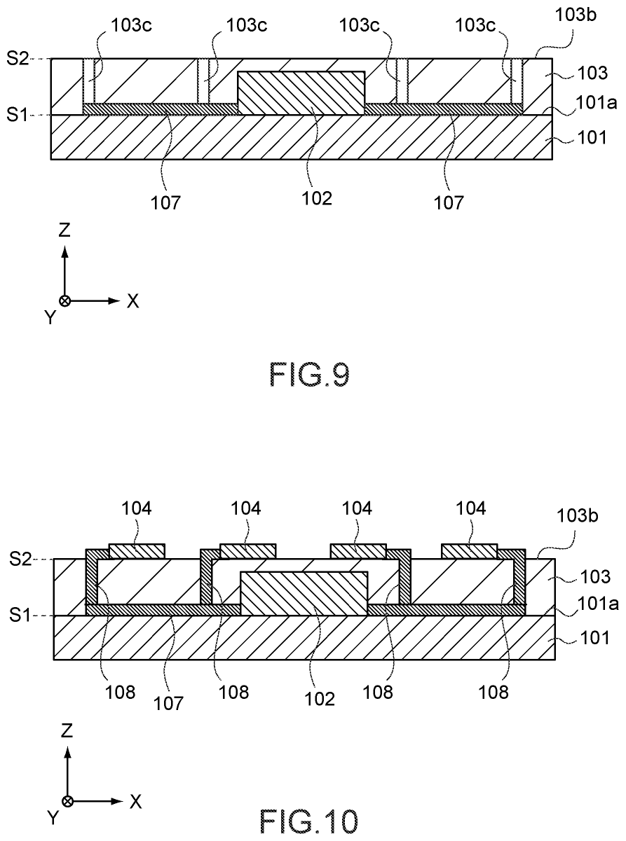

Subsequently, the interlayer insulation layer 103 is stacked on the substrate front surface 101a and on the drive element 102, and a through hole 103c for the second wiring 108 is formed, as illustrated in FIG. 9. Subsequently, the light-emitting element 104 is formed on the second layer surface 103b (the second mounting surface S2) of the interlayer insulation layer 103, as illustrated in FIG. 10. Further, the second wiring 108 is formed using the through hole 103c, and the light-emitting element 104 and the drive element 102 are connected to each other using the second wiring 108.

After the light-emitting element 104 is mounted, the light-emitting element 104 is tested, and an error in the light-emitting element 104 is detected. Examples of the error include a malfunction in the light-emitting element 104 itself, a failure in connection between the light-emitting element 104 and the second wiring 108, and a failure in connection between the drive element 102 and the second wiring 108. When an error has occurred in the light-emitting element 104, the light-emitting element 104 is repaired. In the case of repairing the light-emitting element 104, the light-emitting element 104 may be connected to the second wiring 108 again, or the light-emitting element 104 may be replaced with another light-emitting element 104.

After the light-emitting element 104 is tested, the protection layer 105 and the black matrix 106 are formed, as illustrated in FIG. 1. Accordingly, the light-emitting apparatus 100 can be produced. Note that the light-emitting apparatus 100 can also be produced by a production method that is different from the production method described above.

### [Effects Provided by Light-Emitting Apparatus]

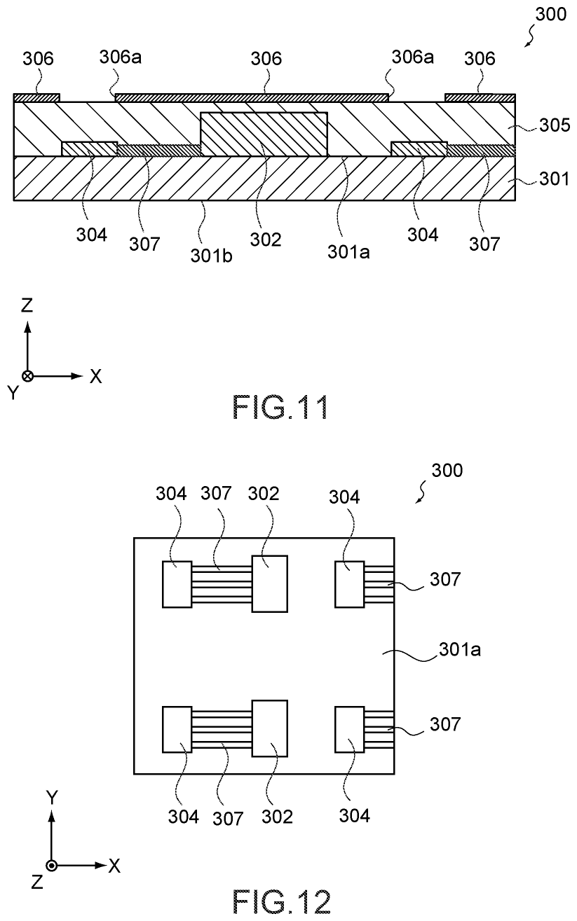

Effects that are provided by the light-emitting apparatus 100 are described in comparison to a comparative example. FIG. 11 is a cross-sectional view of a light-emitting apparatus 300 according to the comparative example, and FIG. 12 is a plan view illustrating a configuration of a portion of the light-emitting apparatus 300. As illustrated in the figures, the light-emitting apparatus 300 includes a substrate 301, a drive element 302, a light-emitting element 304, a protection layer 305, a black matrix 306, and wiring 307. The substrate 301 includes a substrate front surface 301a and a substrate back surface 301b, and the drive element 302 and the light-emitting element 304 are mounted on the substrate front surface 301a.

In a structure of the light-emitting apparatus 300, both the drive element 302 and the light-emitting element 304 are mounted on the substrate front surface 301a. Thus, there is a need to prevent the drive element 302 and the light-emitting element 304 from interfering with each other. This results in difficulty in arranging the light-emitting elements 304 at a high density, as illustrated in FIG. 12. When, in particular, the drive element 302 and the light-emitting element 304 have different heights, a mounting failure occurs easily, and this results in becoming more difficult to arrange the light-emitting elements 304 at a high density. Further, the size of the drive element 302 is also restricted.

On the other hand, in the light-emitting apparatus 100 according to the present embodiment, the drive element 102 is mounted on the first mounting surface S1, and the light-emitting element 104 is mounted on the second mounting surface S2. Thus, there is no need to prevent the drive element 102 and the light-emitting element 104 from interfering with each other. This makes it possible to mount the light-emitting elements 104 at a high density (refer to FIG. 4). Further, it is also possible to make the drive element 102 larger in size, and thus to control a plurality of light-emitting elements 104 using the drive element 102.

Further, in the light-emitting apparatus 100, the drive element 102 can be tested after the drive element 102 is mounted, and the light-emitting element 104 can be mounted after the drive element 102 is repaired, as described above. On the other hand, the drive element 302 and the light-emitting element 304 are tested at the same time in the light-emitting apparatus 300. Thus, when an error occurs, it will be difficult to perform classification into a cause due to the drive element 302 and a cause due to the light-emitting element 304.

If the drive element 302 is tested after only the drive element 302 is mounted and the light-emitting element 304 is mounted after the drive element 302 is repaired, it will be possible to repair an error in the drive element 302. However, in this case, an error may newly occur in, for example, connecting the drive element 302 due to, for example, heat generated upon mounting the light-emitting element 304. On the other hand, in the light-emitting apparatus 100, the light-emitting element 104 can be mounted after the drive element 102 is repaired, and a mounting surface on which the drive element 102 is mounted and a mounting surface on which the light-emitting element 104 is mounted are spaced from each other. This results in easily determining a cause of an error and repairing the error.

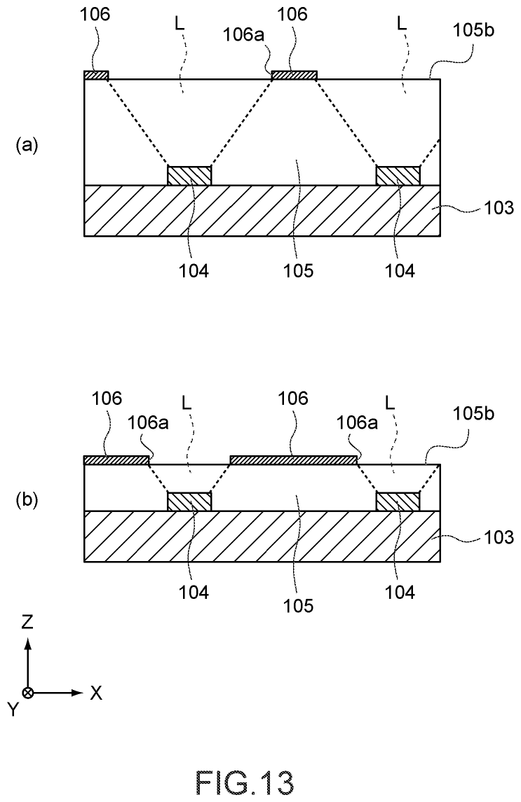

Further, in the light-emitting apparatus 100, the protection layer 105 covering the light-emitting element 104 can be made thinner. In the light-emitting apparatus 300, it is necessary for the protection layer 305 to cover the light-emitting element 304 and the drive element 302. Thus, in general, there is a need to make the protection layer 305 thicker in conformity to the drive element 302 having a large thickness. On the other hand, in the light-emitting apparatus 100, it is sufficient if the protection layer 105 only covers the light-emitting element 104. This makes it possible to make the protection layer 105 thinner. The opening 106a of the black matrix 106 can be made smaller in size by making the protection layer 105 thinner, as described above. FIG. 13 schematically illustrates a relationship between the thickness of the protection layer 105 and the size of the opening 106a.

When the light L incident from the light-emitting element 104 exhibits a high degree of intensity, this results in a deterioration in the black matrix 106. Thus, the opening 106a is provided to a region in which the intensity of the light L is greater than or equal to a threshold, and the black matrix 106 is formed only in a region in which the intensity of the light L is less than the threshold. (a) of FIG. 13 schematically illustrates the case in which the protection layer 105 is thick, and (b) of FIG. 13 schematically illustrates the case in which the protection layer 105 is thin. When the light-emitting elements 104 are equally spaced, a range in which the light L exhibiting the intensity greater than or equal to a specified intensity is incident on the fourth layer surface 105b is narrower and thus the opening 106a can be made smaller in size if the protection layer 105 is thinner, as illustrated in the figures. This results in an increase in an area ratio of a region covered with the black matrix 106 in the fourth layer surface 105b. This makes it possible to increase the proportion of black.

Further, in the light-emitting apparatus 100, the interlayer insulation layer 103 is provided between the drive element 102 and the light-emitting element 104. Thus, optical guiding that causes light emitted by the light-emitting element 104 to reach the drive element 102 is suppressed by the interlayer insulation layer 103. This makes it possible to reduce malfunctions in the drive element 102 that are caused due to optical guiding. When, in particular, the interlayer insulation layer 103 exhibits a light transmittance less than or equal to 1% at a wavelength of light emitted by the light-emitting element 104, this makes it possible to further reduce malfunctions in the drive element 102 that are caused due to optical guiding.

### [Modifications]

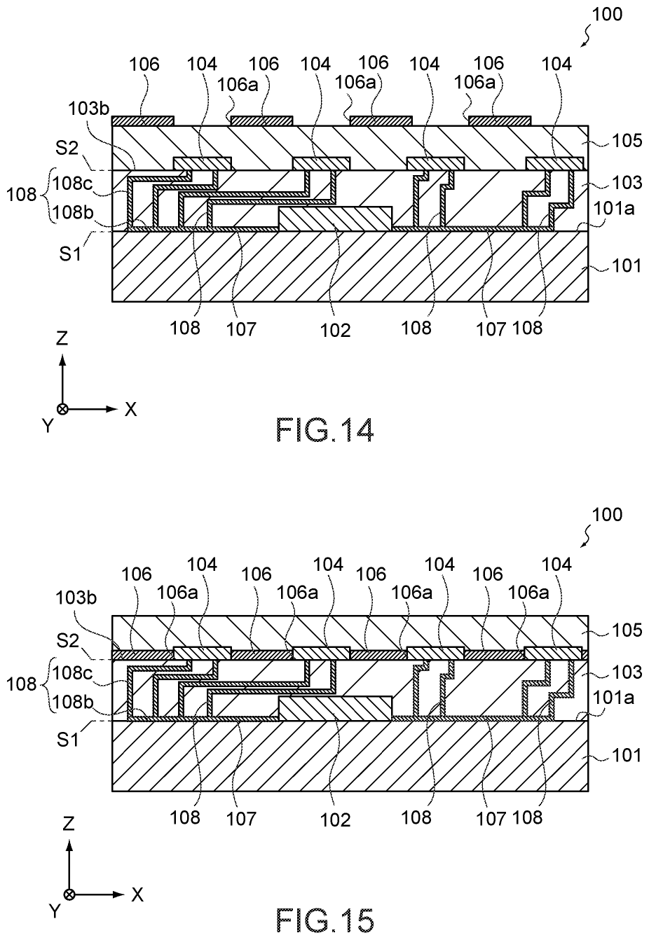

Modifications of the light-emitting apparatus 100 according to the present embodiment are described. FIGS. 14 to 20 are cross-sectional views of the light-emitting apparatus 100 according to the modifications.

As illustrated in FIG. 14, the second wiring 108 may be connected to a back surface of the light-emitting element 104, and may only include the second portion 108b and the third portion 108c without the first portion 108a (refer to FIG. 5). In other words, the second wiring 108 may be wiring that is provided on the first mounting surface S1 and in the interlayer insulation layer 103 and is not provided on the second mounting surface S2. In this configuration, the second wiring 108 is not on the second layer surface 103b, and thus the second wiring 108 is not seen through the opening 106a of the black matrix 106. This makes it possible to improve the image quality provided by the light-emitting apparatus 100.

Further, as illustrated in FIG. 15, the black matrix 106 may be arranged on the second layer surface 103b (the second mounting surface S2). Since the second wiring 108 does not include the first portion 108a, as illustrated in FIG. 14, the black matrix 106 can be arranged on the second layer surface 103b. In this configuration, the black matrix 106 can be formed to be adjacent to a peripheral edge of the light-emitting element 104. This makes it possible to further increase the proportion of black, and thus to improve the image quality.

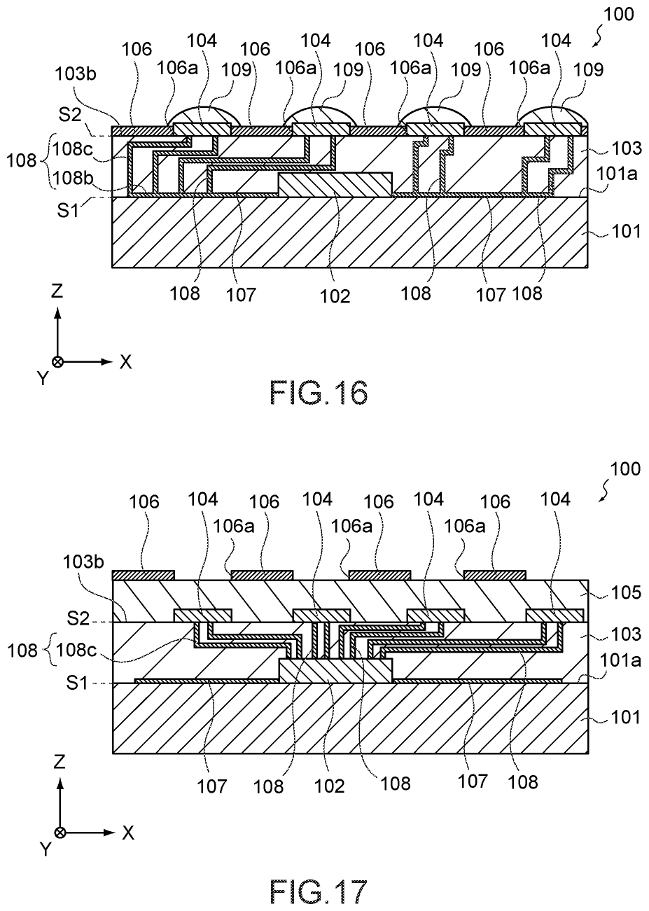

Furthermore, as illustrated in FIG. 16, a sealing body 109 may be provided instead of the protection layer 105. The sealing body 109 covers to seal each light-emitting element 104. A material of the sealing body 109 may be any insulating material, and is favorably a material exhibiting a high degree of light transmittance at a wavelength of light emitted by the light-emitting element 104. Since the black matrix 106 is arranged on the second layer surface 103b, as illustrated in FIG. 15, the sealing body 109 can be provided instead of the protection layer 105. This makes it possible to improve the material efficiency.

Moreover, as illustrated in FIG. 17, the second wiring 108 may be connected to an upper surface of the drive element 102, and may only include the third portion 108c without the first portion 108a or the second portion 108b (refer to FIG. 5). In other words, the second wiring 108 may be wiring that is provided in the interlayer insulation layer 103 and is not provided on the first mounting surface S1 or on the second mounting surface S2. This configuration makes it possible to reduce a degree of wiring density on the substrate front surface 101a, and thus to improve the yield rate of the light-emitting apparatus 100.

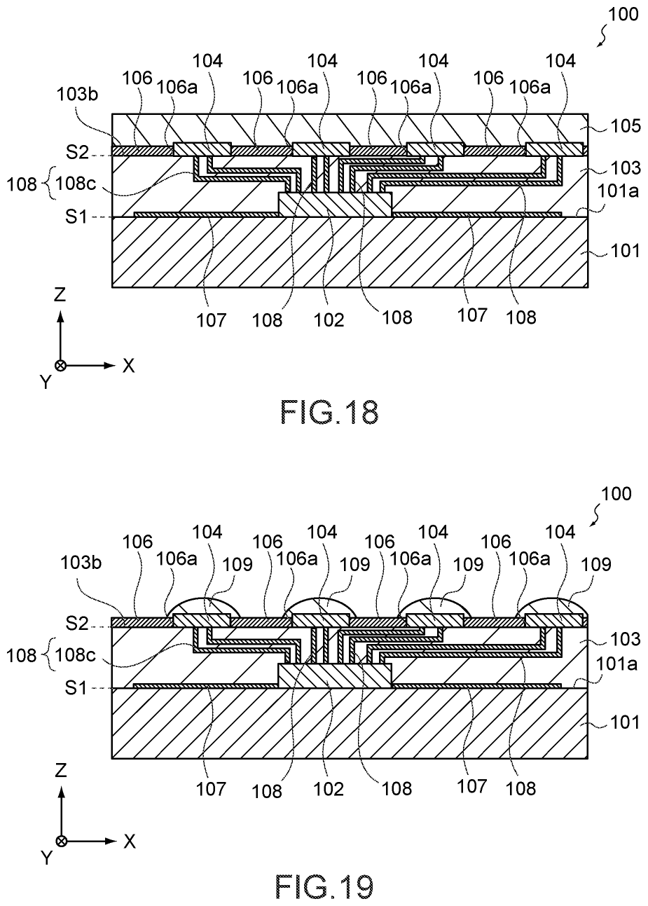

Further, as illustrated in FIG. 18, the black matrix 106 may also be arranged on the second layer surface 103b (the second mounting surface S2) in the configuration of FIG. 17. This configuration also makes it possible to further increase the proportion of black, and thus to improve the image quality, compared to the configuration of FIG. 17. Furthermore, as illustrated in FIG. 19, the sealing body 109 may also be provided instead of the protection layer 105 in the configuration of FIG. 17. This configuration also makes it possible to improve the material efficiency.

Note that the second wiring 108 may only include the first portion 108a and the third portion 108c without the second portion 108b (refer to FIG. 5). In other words, the second wiring 108 may also be wiring that is provided on the second mounting surface S2 and in the interlayer insulation layer 103 and is not provided on the first mounting surface S1.

As described above, the light-emitting apparatus 100 may have various configurations. Note that the protection layer 105 and the sealing body 109 do not necessarily have to be provided in each of the configurations described above. Further, the substrate front surface 101a corresponds to the first mounting surface S1, and the second layer surface 103b corresponds to the second mounting surface S2. However, the configuration is not limited thereto. It is sufficient if the first mounting surface S1 is a surface that is situated on the side of the substrate front surface 101a of the substrate 101, the second mounting surface S2 is a surface that is situated on the side of the substrate front surface 101a of the substrate 101, and the second mounting surface S2 is situated farther away from the substrate front surface 101a than the first mounting surface S1.

### Second Embodiment

A light-emitting apparatus according to the second embodiment of the present technology is described.

### [Structure of Light-Emitting Apparatus]

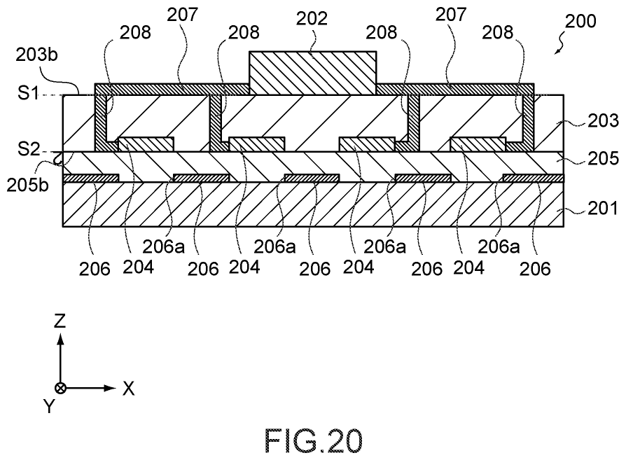

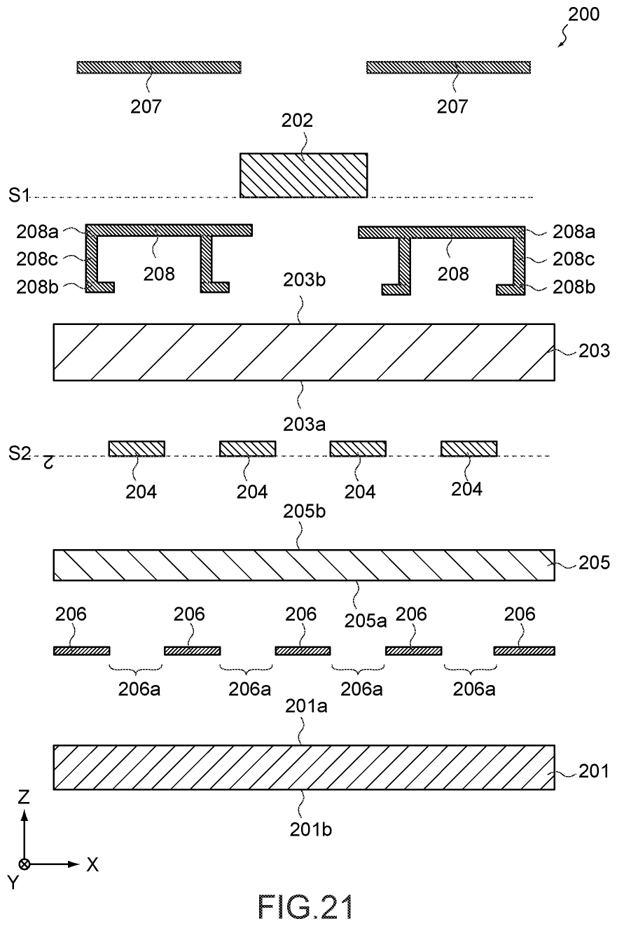

A structure of the light-emitting apparatus according to the present embodiment is described. FIG. 20 is a cross-sectional view of a light-emitting apparatus 200 according to the present embodiment, and FIG. 21 is an exploded cross-sectional view of the light-emitting apparatus 200. The light-emitting apparatus 200 is the light-emitting apparatus 100 according to the first embodiment of which the top-emitting structure has been replaced with a bottom-emitting structure.

As illustrated in FIGS. 20 and 21, the light-emitting apparatus 200 includes a substrate 201, a drive element 202, an interlayer insulation layer 203, a light-emitting element 204, a protection layer 205, a black matrix 206, first wiring 207, and second wiring 208. The substrate 201 supports each layer of the light-emitting apparatus 200. As illustrated in FIG. 21, the substrate 201 includes a substrate front surface 201a and a substrate back surface 201b that is a surface situated opposite to the substrate front surface 201a. A material of the substrate 201 is not particularly limited, and may be, for example, glass or an organic material.

The drive element 202 drives the light-emitting element 204. The drive element 202 may be a thin film transistor (TFT) or an integrated circuit. As illustrated in FIG. 21, the drive element 202 is mounted on the first mounting surface S1. As illustrated in FIG. 20, the first mounting surface S1 may be a second layer surface 203b that is included in the interlayer insulation layer 203. FIG. 20 illustrates a single drive element 202, but the light-emitting apparatus 200 may include a plurality of drive elements 202 arranged in a matrix. Further, the light-emitting apparatus 200 may include a single drive element 202.

The interlayer insulation layer 203 is formed between the drive element 202 and the light-emitting element 204, and insulates the drive element 202 from the light-emitting element 204. The interlayer insulation layer 203 may be stacked on the protection layer 205 and on the light-emitting element 204. As illustrated in FIG. 21, from among layer surfaces of the interlayer insulation layer 203, a surface situated on a side of the substrate front surface 201a is referred to as a first layer surface 203a, and a surface situated opposite to the first layer surface 203a is referred to as the second layer surface 203b. A material of the interlayer insulation layer 203 may be any insulating material, and is favorably a material exhibiting excellent light-blocking properties. The interlayer insulation layer 203 favorably exhibits a light transmittance less than or equal to 1% at a wavelength of light emitted by the light-emitting element 204.

The light-emitting element 204 emits light. The light-emitting element 204 may be a semiconductor light-emitting element such as a light-emitting diode (LED) or a laser diode (LD), and may be used as, for example, a pixel (pixels of R, G, and B) of a display, or a light source of a backlight. The wavelength of light emitted by the light-emitting element 204 is not limited to wavelengths of, for example, visible light, ultraviolet light, and infrared light. The respective light-emitting elements 204 may emit light at different wavelengths. As illustrated in FIG. 21, the light-emitting element 204 is mounted on the second mounting surface S2. As illustrated in FIG. 20, the second mounting surface S2 may be a fourth layer surface 205b that is included in the protection layer 205. The light-emitting apparatus 200 may include a plurality of light-emitting elements 204 arranged in a matrix. Alternatively, the light-emitting apparatus 200 may include a single light-emitting element 204.

The protection layer 205 covers the light-emitting element 204, and protects the light-emitting element 204. The protection layer 205 may be stacked on the substrate front surface 201a and on the black matrix 206. As illustrated in FIG. 21, from among layer surfaces of the protection layer 205, a surface situated on the side of the substrate front surface 201a is referred to as a third layer surface 205a, and a surface situated opposite to the third layer surface 205a is referred to as the fourth layer surface 205b. A material of the protection layer 205 may be any insulating material, and is favorably a material exhibiting a high degree of light transmittance at a wavelength of light emitted by the light-emitting element 204.

The black matrix 206 absorbs incident light. The black matrix 206 may be formed on the substrate front surface 201a. As illustrated in FIG. 21, the black matrix 206 includes an opening 206a. The opening 206a faces the light-emitting element 204, and is formed such that the black matrix 206 does not block light emitted by the light-emitting element 204. The first wiring 207 is wiring that is connected to the drive element 202. As illustrated in FIG. 20, the first wiring 207 is provided on the second layer surface 203a, that is, on the first mounting surface S1. The second wiring 207 is made of any conductive material.

The second wiring 208 is wiring that connects the drive element 202 and the light-emitting element 204. As illustrated in FIG. 21, the second wiring 208 includes a first portion 208a, a second portion 208b, and a third portion 208c. The first portion 208a is connected to the drive element 202 and provided on the second layer surface 203b, that is, on the first mounting surface S1. The second portion 208b is connected to the light-emitting element 204 and provided on the fourth layer surface 205b, that is, on the second mounting surface S2. The third portion 208c connects the first portion 208a and the second portion 208b and provided in the interlayer insulation layer 203. Note that the first portion 208a is provided on the second layer surface 203b to be spaced from the first wiring 207. The second wiring 208 is made of any conductive material.

### [Regarding First Mounting Surface and Second Mounting Surface]

Also in the second embodiment, the drive element 202 is arranged on the first mounting surface S1, and the light-emitting element 204 is arranged on the second mounting surface S2. Both the first mounting surface S1 and the second mounting surface S2 are surfaces that are situated on the side of the substrate front surface 201a of the substrate 201 and parallel to the layer plane (the X-Y plane) of each layer. Here, conversely to the first embodiment, the first mounting surface S1 may be situated farther away from the substrate front surface 201a than the second mounting surface S2.

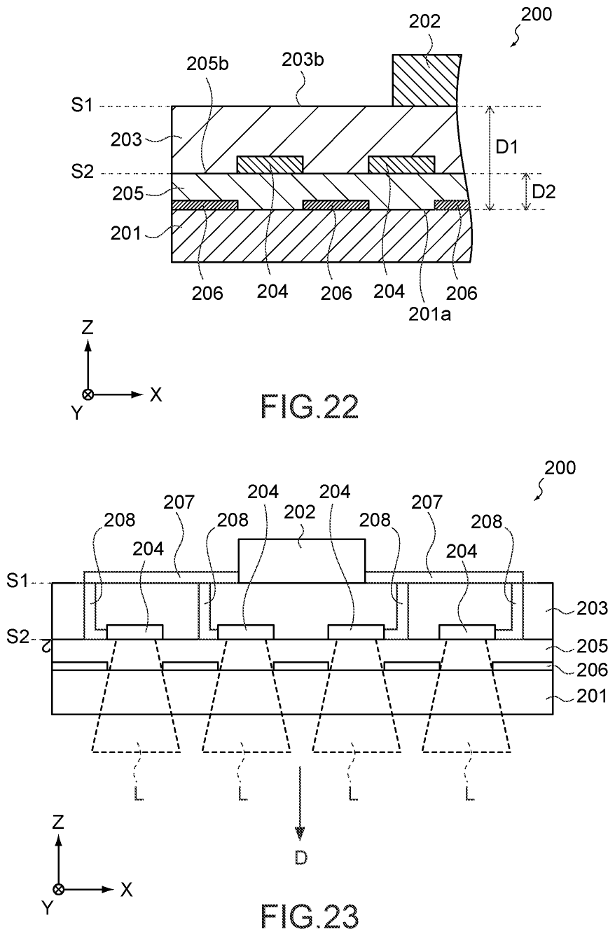

FIG. 22 schematically illustrates a distance between the first mounting surface S1 and the substrate front surface 201a and a distance between the second mounting surface S2 and the substrate front surface 201a. When the distance between the first mounting surface S1 and the substrate front surface 201a is referred to as the distance D1 and the distance between the second mounting surface S2 and the substrate front surface 201a is referred to as the distance D2, the distance D1 may be larger than the distance D2, as illustrated in the figure.

The light-emitting apparatus 200 has the configuration above. The number of light-emitting elements 204 connected to a single drive element 202 is also not particularly limited in the light-emitting apparatus 200, and may be any number that is at least one.

### [Operation of Light-Emitting Apparatus]

An operation of the light-emitting apparatus 200 is described. FIG. 23 schematically illustrates the operation of the light-emitting apparatus 200. Also in the light-emitting apparatus 200, when a drive signal is supplied to the drive element 202 from the outside through the first wiring 207, the drive element 202 generates a drive signal for each light-emitting element 204, and supplies the generated drive signal to the light-emitting element 204 through the second wiring 208. When the drive signal is supplied to each light-emitting element 204 by the drive element 202, the light-emitting element 204 emits the light L, as illustrated in FIG. 23. The light L coming from the light-emitting element 204 is transmitted through the protection layer 205 and the substrate 201, and passes through the opening 206a (refer to FIG. 21) of the black matrix 206 to be emitted.

A direction in which the light L is emitted by the light-emitting apparatus 200 is referred to as the light-emission direction D, as indicated by an arrow in FIG. 23. As described above, the light-emitting apparatus 200 may have a bottom-emitting structure in which the light L is emitted in a direction of the substrate 201.

With respect to a relationship between the light-emitting direction D, the first mounting surface S1, and the second mounting surface S2, the first mounting surface S1 is situated opposite to the orientation of the light-emitting direction D with respect to the second mounting surface S2. This results in the drive element 202 not blocking the light L emitted by the light-emitting element 204, and thus in being able to increase a degree of freedom in the size and arrangement of the drive element 202.

### [Method for Producing Light-Emitting Apparatus]

A method for producing the light-emitting apparatus 200 is described. As in the case of the method for producing the light-emitting apparatus 100, the drive element 202 and the light-emitting element 204 can be mounted in different steps and individually tested by the method for producing the light-emitting apparatus 200. Specifically, the light-emitting element 204 is mounted on the fourth layer surface 205b (refer to FIG. 20) corresponding to the second mounting surface S2 and connected to the second wiring 208. Thereafter, the light-emitting element 204 is tested, and an error in the light-emitting element 204 is detected. When an error has occurred in the light-emitting element 204, the light-emitting element 204 is repaired.

Subsequently, the interlayer insulation layer 203 is stacked, and the drive element 202 is mounted on the second layer surface 203b corresponding to the first mounting surface S1 and connected to the first wiring 207. Thereafter, the drive element 202 is tested, and an error in the drive element 202 is detected. When an error has occurred in the drive element 202, the drive element 202 is repaired.

The light-emitting apparatus 200 can be produced as described above. Note that the light-emitting apparatus 200 can also be produced by a production method that is different from the production method described above.

### [Effects Provided by Light-Emitting Apparatus]

The light-emitting apparatus 200 provides effects that are similar to those provided by the light-emitting apparatus 100. In other words, the drive element 202 is mounted on the first mounting surface S1, and the light-emitting element 204 is mounted on the second mounting surface S2. This makes it possible to mount the light-emitting elements 204 at a high density, and also makes it possible to make the drive element 202 larger in size.

Further, in the light-emitting apparatus 200, the drive element 202 can be mounted after the light-emitting element 204 is repaired, and a mounting surface on which the drive element 202 is mounted and a mounting surface on which the light-emitting element 204 is mounted are spaced from each other. This results in easily determining a cause of an error and repairing the error. Furthermore, in the light-emitting apparatus 200, the protection layer 205 covering the light-emitting element 204 can be made thinner. This makes it possible to make the opening 206a of the black matrix 206 smaller in size, and thus to increase the proportion of black.

Moreover, in the light-emitting apparatus 200, the interlayer insulation layer 203 is provided between the drive element 202 and the light-emitting element 204. Thus, optical guiding performed from the light-emitting element 204 to the drive element 102 is suppressed. This makes it possible to reduce malfunctions in the drive element 202 that are caused due to optical guiding.

### [Modifications]

In the light-emitting apparatus 200, the second layer surface 203b corresponds to the first mounting surface S1, and the fourth layer surface 205b corresponds to the second mounting surface S2. However, the configuration is not limited thereto. It is sufficient if the first mounting surface S1 is a surface that is situated on the side of the substrate front surface 201a of the substrate 201, the second mounting surface S2 is a surface that is situated on the side of the substrate front surface 201a of the substrate 201, and the first mounting surface S1 is situated farther away from the substrate front surface 201a than the second mounting surface S2.

### Regarding Present Disclosure

The effects described in the present disclosure are not limitative but are merely illustrative, and other effects may be provided. The above-described description of the plurality of effects does not necessarily mean that the plurality of effects is provided at the same time. The above-described description means that at least one of the effects described above is provided depending on, for example, a condition. There is a possibility that an effect that is not described in the present disclosure will be provided. Further, at least two of the features of the present disclosure described above can also be combined discretionarily.

Note that the present technology may also take the following configurations.
(1) A light-emitting apparatus, including:
   a substrate that includes a substrate front surface and a substrate back surface that is situated opposite to the substrate front surface;
   a drive element that is mounted on a first mounting surface on a side of the substrate front surface of the substrate;
   a light-emitting element that is mounted on a second mounting surface on the side of the substrate front surface of the substrate, the second mounting surface being situated at a distance, from the substrate front surface, that is different from a distance of the first mounting surface from the substrate front surface; and
   an interlayer insulation layer that is made of an insulating material and formed between the drive element and the light-emitting element.
(2) The light-emitting apparatus according to (1), in which
   when a direction in which light emitted by the light-emitting element is emitted is a light-emitting direction, the first mounting surface is situated opposite to an orientation of the light-emitting direction with respect to the second mounting surface.
(3) The light-emitting apparatus according to (1) or (2), further including
   a black matrix that is arranged on the side of the substrate front surface of the substrate and absorbs incident light, the black matrix including an opening that faces the light-emitting element.
(4) The light-emitting apparatus according to (3), further including
   a protection layer that covers the light-emitting element, in which
   the black matrix is arranged on the protection layer.
(5) The light-emitting apparatus according to (3), in which
   the black matrix is arranged on the second mounting surface.
(6) The light-emitting apparatus according to any one of (1) to (5), in which
   the second mounting surface is situated farther away from the substrate front surface than the first mounting surface.
(7) The light-emitting apparatus according to (6), in which
   the interlayer insulation layer is stacked on the substrate front surface, the interlayer insulation layer including a first layer surface and a second layer surface, the first layer surface being situated on the side of the substrate front surface, the second layer surface being situated opposite to the first layer surface,
   the first mounting surface is the substrate front surface, and
   the second mounting surface is the second layer surface.
(8) The light-emitting apparatus according to any one of (1) to (5), in which
   the first mounting surface is situated farther away from the substrate front surface than the second mounting surface.
(9) The light-emitting apparatus according to (8), further including
   a protection layer that is stacked on the substrate front surface, in which
   the interlayer insulation layer is stacked on the protection layer, the interlayer insulation layer including a first layer surface and a second layer surface, the first layer surface being situated on the side of the substrate front surface, the second layer surface being situated opposite to the first layer surface,
   the protection layer includes a third layer surface and a fourth layer surface, the third layer surface being situated on the side of the substrate front surface, the fourth layer surface being situated opposite to the third layer surface,
   the first mounting surface is the second layer surface, and
   the second mounting surface is the fourth layer surface.
(10) The light-emitting apparatus according to any one of (1) to (9), further including:
   first wiring that is provided on the first mounting surface and connected to the drive element, and
   second wiring that connects the drive element and the light-emitting element.
(11) The light-emitting apparatus according to (10), in which
   the second wiring is provided on the first mounting surface, on the second mounting surface, and in the interlayer insulation layer.
(12) The light-emitting apparatus according to (10), in which
   the second wiring is provided in the interlayer insulation layer and is not provided on the second mounting surface.
(13) The light-emitting apparatus according to (12), in which
   a black matrix that absorbs incident light and includes an opening that faces the light-emitting element, is arranged on the second mounting surface.
(14) The light-emitting apparatus according to (12), in which
   a sealing body that seals the light-emitting element is provided on the second mounting surface.
(15) The light-emitting apparatus according to (10), in which
   the second wiring is provided in the interlayer insulation layer and is not provided on the first mounting surface.
(16) The light-emitting apparatus according to any one of (1) to (15), in which
   the interlayer insulation layer shields the drive element from light emitted by the light-emitting element.
(17) The light-emitting apparatus according to any one of (1) to (16), in which
   the drive element is a thin film transistor.
(18) The light-emitting apparatus according to any one of (1) to (16), in which
   the drive element is an integrated circuit.
(19) A method for producing a light-emitting apparatus, the method including:
   mounting a drive element on a first mounting surface on a side of a substrate front surface of a substrate, the substrate including the substrate front surface and a substrate back surface that is situated opposite to the substrate front surface;
   connecting the drive element and first wiring on the side of the substrate front surface of the substrate;
   testing the drive element;
   when an error has occurred in the drive element, repairing the drive element in which the error has occurred;
   mounting a light-emitting element on a second mounting surface on the side of the substrate front surface of the substrate, the second mounting surface being situated at a distance, from the substrate front surface, that is different from a distance of the first mounting surface from the substrate front surface;
   connecting the light-emitting element and second wiring on the side of the substrate front surface of the substrate;
   testing the light-emitting element; and
   when an error has occurred in the light-emitting element, repairing the light-emitting element in which the error has occurred.
(20) A method for producing a light-emitting apparatus, the method including:
   mounting a light-emitting element on a second mounting surface on a side of a substrate front surface of a substrate, the substrate including the substrate front surface and a substrate back surface that is situated opposite to the substrate front surface;
   connecting the light-emitting element and second wiring on the side of the substrate front surface of the substrate;
   testing the light-emitting element;
   when an error has occurred in the light-emitting element, repairing the light-emitting element in which the error has occurred;
   mounting a drive element on a first mounting surface on the side of the substrate front surface of the substrate, the first mounting surface being situated at a distance, from the substrate front surface, that is different from a distance of the second mounting surface from the substrate front surface;
   connecting the drive element and first wiring on the side of the substrate front surface of the substrate;
   testing the drive element; and
   when an error has occurred in the drive element, repairing the drive element in which the error has occurred.

### REFERENCE SIGNS LIST

100, 200 light-emitting apparatus
101, 201 substrate
102, 202 drive element
103, 203 interlayer insulation layer
104, 204 light-emitting element
105, 205 protection layer
106, 206 black matrix
107, 207 first wiring
108, 208 second wiring
109 sealing body

What is claimed is:

1. A light-emitting apparatus, comprising:
a substrate that includes a substrate front surface and a substrate back surface that is situated opposite to the substrate front surface;
a drive element that is mounted on a first mounting surface on a side of the substrate front surface of the substrate;
a light-emitting element that is mounted on a second mounting surface on the side of the substrate front surface of the substrate, the second mounting surface being situated at a distance, from the substrate front surface, that is different from a distance of the first mounting surface from the substrate front surface; and
an interlayer insulation layer that is made of an insulating material and formed between the drive element and the light-emitting element.

2. The light-emitting apparatus according to claim 1, wherein
when a direction in which light emitted by the light-emitting element is emitted is a light-emitting direction, the first mounting surface is situated opposite to an orientation of the light-emitting direction with respect to the second mounting surface.

3. The light-emitting apparatus according to claim 1, further comprising
a black matrix that is arranged on the side of the substrate front surface of the substrate and absorbs incident light, the black matrix including an opening that faces the light-emitting element.

4. The light-emitting apparatus according to claim 3, further comprising
a protection layer that covers the light-emitting element, wherein
the black matrix is arranged on the protection layer.

5. The light-emitting apparatus according to claim 3, wherein
the black matrix is arranged on the second mounting surface.

6. The light-emitting apparatus according to claim 1, wherein
the second mounting surface is situated farther away from the substrate front surface than the first mounting surface.

7. The light-emitting apparatus according to claim 6, wherein
the interlayer insulation layer is stacked on the substrate front surface, the interlayer insulation layer including a first layer surface and a second layer surface, the first layer surface being situated on the side of the substrate front surface, the second layer surface being situated opposite to the first layer surface,
the first mounting surface is the substrate front surface, and
the second mounting surface is the second layer surface.

8. The light-emitting apparatus according to claim 1, wherein
the first mounting surface is situated farther away from the substrate front surface than the second mounting surface.

9. The light-emitting apparatus according to claim 8, further comprising
a protection layer that is stacked on the substrate front surface, wherein
the interlayer insulation layer is stacked on the protection layer, the interlayer insulation layer including a first layer surface and a second layer surface, the first layer surface being situated on the side of the substrate front surface, the second layer surface being situated opposite to the first layer surface,
the protection layer includes a third layer surface and a fourth layer surface, the third layer surface being situated on the side of the substrate front surface, the fourth layer surface being situated opposite to the third layer surface,
the first mounting surface is the second layer surface, and
the second mounting surface is the fourth layer surface.

10. The light-emitting apparatus according to claim 1, further comprising:
first wiring that is provided on the first mounting surface and connected to the drive element, and second wiring that connects the drive element and the light-emitting element.

11. The light-emitting apparatus according to claim 10, wherein
the second wiring is provided on the first mounting surface, on the second mounting surface, and in the interlayer insulation layer.

12. The light-emitting apparatus according to claim 10, wherein
the second wiring is provided in the interlayer insulation layer and is not provided on the second mounting surface.

13. The light-emitting apparatus according to claim 12, wherein
a black matrix that absorbs incident light and includes an opening that faces the light-emitting element, is arranged on the second mounting surface.

14. The light-emitting apparatus according to claim 12, wherein
a sealing body that seals the light-emitting element is provided on the second mounting surface.

15. The light-emitting apparatus according to claim 10, wherein
the second wiring is provided in the interlayer insulation layer and is not provided on the first mounting surface.

16. The light-emitting apparatus according to claim 1, wherein
the interlayer insulation layer shields the drive element from light emitted by the light-emitting element.

17. The light-emitting apparatus according to claim 1, wherein
the drive element is a thin film transistor.

18. The light-emitting apparatus according to claim 1, wherein
the drive element is an integrated circuit.

19. A method for producing a light-emitting apparatus, the method comprising:
mounting a drive element on a first mounting surface on a side of a substrate front surface of a substrate, the substrate including the substrate front surface and a substrate back surface that is situated opposite to the substrate front surface;
connecting the drive element and first wiring on the side of the substrate front surface of the substrate;
testing the drive element;
when an error has occurred in the drive element, repairing the drive element in which the error has occurred;
mounting a light-emitting element on a second mounting surface on the side of the substrate front surface of the substrate, the second mounting surface being situated at a distance, from the substrate front surface, that is different from a distance of the first mounting surface from the substrate front surface;
connecting the light-emitting element and second wiring on the side of the substrate front surface of the substrate;
testing the light-emitting element; and
when an error has occurred in the light-emitting element, repairing the light-emitting element in which the error has occurred.

20. A method for producing a light-emitting apparatus, the method comprising:
mounting a light-emitting element on a second mounting surface on a side of a substrate front surface of a substrate, the substrate including the substrate front surface and a substrate back surface that is situated opposite to the substrate front surface;
connecting the light-emitting element and second wiring on the side of the substrate front surface of the substrate;
testing the light-emitting element;
when an error has occurred in the light-emitting element, repairing the light-emitting element in which the error has occurred;
mounting a drive element on a first mounting surface on the side of the substrate front surface of the substrate, the first mounting surface being situated at a distance, from the substrate front surface, that is different from a distance of the second mounting surface from the substrate front surface;
connecting the drive element and first wiring on the side of the substrate front surface of the substrate;
testing the drive element; and
when an error has occurred in the drive element, repairing the drive element in which the error has occurred.
